(19) United States
(12) Patent Application Publication
(10) Pub. No.: US 2018/0094871 A1
(43) Pub. Date: Apr. 5, 2018

(54) Two-Phase Cooling Devices with Low-Profile Charging Ports

(71) Applicants: PiMEMS, Inc., Santa Barbara, CA (US); The Regents of the University of California, Oakland, CA (US)

(72) Inventors: Payam Bozorgi, Santa Barbara, CA (US); Carl D. Meinhart, Santa Barbara, CA (US)

(73) Assignees: PiMEMS, Inc., Santa Barbara, CA (US); The Regents of the University of California, Oakland, CA (US)

(21) Appl. No.: 15/706,706

(22) Filed: Sep. 16, 2017

Related U.S. Application Data
(62) Division of application No. 14/749,439, filed on Jun. 24, 2015.
(60) Provisional application No. 62/017,455, filed on Jun. 26, 2014.

(51) Int. Cl. F28D 15/02; H01L 23/427

(52) U.S. Cl. CPC F28D 15/0283; H01L 23/427

(57) ABSTRACT

A two-phase cooling device, including a predetermined amount of at least one working fluid, a cavity formed from at least one of a metal structure or a metal alloy structure, at least one opening formed in the structure, wherein said opening is configured as a port for partial filling of the cavity with the at least one working fluid, and at least one cover for said opening, wherein said cover is configured to be sealed to the opening, to prevent said working fluid from leaving the cavity, and to prevent contaminants and non-condensable gas from entering the cavity.

### RELATED APPLICATIONS

This application claims priority to U.S. Provisional Application 62/017,455, filed Jun. 26, 2014.

The following co-pending, with common inventorship and common ownership, U.S. patent applications are incorporated by reference in their entirety:

U.S. Patent Application Ser. No. 61/082,437, filed on Jul. 21, 2008, by Noel C. MacDonald et al., entitled “TITANIUM-BASED THERMAL GROUND PLANE,” which application is incorporated by reference herein.

U.S. patent application Ser. No. 13/685,579, filed on Nov. 26, 2012, by Payam Bozorgi et al., entitled “TITANIUM-BASED THERMAL GROUND PLANE,” which application is incorporated by reference herein.

PCT Application No. PCT/US2012/023303, filed on Jan. 31, 2012, by Payam Bozorgi and Noel C. MacDonald, entitled “USING MILLISECOND PULSED LASER WLEDING IN MEMS PACKAGING,” which application is incorporated by reference herein.

### STATEMENT REGARDING FEDERALLY SPONSORED RESEARCH OR DEVELOPMENT

This application is partially based on work accomplished with Government support under Grant (or contract) No. W9113M-04-01-0001 and Grant No. W31P4Q-10-1-0010 awarded by the U.S. Army. The Government has certain rights in this invention.

### BACKGROUND

This application relates to cooling of semiconductor devices, and, more particularly, to two-phase cooling devices to cool semiconductor devices, power electronics, batteries, and other devices.

Electronics employing various semiconductor devices and integrated circuits are may be subjected to various environmental stresses. Applications of such electronics are extremely widespread, and utilize different semiconductor materials.

Many electronic environments, such as mobile devices or laptop computers may have thin/planar configurations, where many components are efficiently packed into a very confined space. As a result, cooling solutions that conform to thin/planar configurations may be beneficial. Charging ports that protrude substantially beyond the actual cooling device may occupy additional space. The additional space requirements for such charging ports may make them undesirable for many space constrained applications.

Low-profile charging ports disclosed herein may in some cases provide efficient space utilization to cool semiconductor devices in a large range of applications, including but not limited to aircraft, satellites, laptop computers, desktop computers, mobile devices, electric vehicles, and data centers.

### SUMMARY

The present application discloses two-phase cooling devices with low-profile ports. Two-phase cooling devices are a class of devices that can transfer heat with very high efficiency, and may include: heat pipes, thermal ground planes, vapor chambers and thermosiphons, and the like. Two-phase cooling devices may be ‘charged’ with one or more working fluids that exist in a liquid/vapor state, where the fluid adsorbs and releases thermal energy due to a phase change between the liquid and vapor state. It may be desirable to remove any contaminants while optionally leaving a small predetermined amount of non-condensable gas, during the charging process. Once the two-phase cooling device is charged through the port, the port may be hermetically sealed.

In some embodiments, the present application provides two-phase cooling devices with low-profile ports. In some embodiments, the two-phase device may comprise a predetermined amount of at least one working fluid, where the working fluid adsorbs or rejects heat by changing phases between liquid and vapor. In some embodiments, the two-phase device may further comprise a cavity formed from a metal structure or a metal alloy structure with at least one opening formed in at least one surface of the structure, wherein said opening may be configured as a port for partial filling of the cavity with the predetermined amount of at least one working fluid. In some embodiments, the two-phase device further may comprise at least one cover for said opening. In some embodiments, the cover may be configured to seal the cavity, to prevent the working fluid from leaving the cavity, and to prevent contaminants and non-condensable gas from entering the cavity.

In some embodiments, the application further provides a method for charging two-phase cooling devices with low profile ports, by first forming a cavity from a metal structure or a metal alloy structure. At least one opening may then be formed in the structure. A predetermined amount of working fluid may then be added through the opening to the inside of the cavity. The entire structure may then be exposed to a sufficiently low temperature, thereby freezing the working fluid inside the cavity. Once frozen, the structure may be exposed to low ambient pressure to extract contaminants, while optionally leaving a small predetermined amount of non-condensable gas in the cavity. The opening may then be covered by at least one cover. The cover maybe bonded to the structure, thereby sealing the cavity to prevent the working fluid from leaving the cavity, and to prevent contaminants and non-condensable gas from entering the cavity.

### BRIEF DESCRIPTION OF THE DRAWINGS

Referring now to the drawings in which like reference numbers represent corresponding parts throughout:

FIG. 1 illustrates a current solution for sealing heat pipes using a protrusion from the heat pipe that is cold welded (i.e. clamped).

FIG. 2 illustrates a current solution for having ports on relatively planar thermal ground planes, where the ports protrude substantially in the out-of-plane direction from the thermal ground plane.

FIG. 3 illustrates a schematic of a Ti-based thermal ground plane, comprising cavity formed from a metal structure 300 according to an illustrative embodiment.

FIG. 4a and FIG. 4b show a Ti-based thermal ground plane, with an opening in the surface of the metal structure, to provide a port for placing a predetermined amount of suitable working fluid into the cavity through a charging port according to an illustrative embodiment.

FIG. 5a and FIG. 5b show a glass vacuum chamber charging apparatus that is used to charge the Ti-based thermal ground plane (TGP) according to an illustrative embodiment.

FIGS. 6a and 6b illustrates components of the two-phase cooling device according to an illustrative embodiment.

FIG. 7 shows a flowchart showing a method according to an illustrative embodiment.

FIGS. 8a, b, c and d show schematics of various illustrative device embodiments.

FIG. 9 shows a flowchart showing an alternative method according to an embodiment.

FIG. 10 illustrates components of an insulator device according to an illustrative embodiment.

FIG. 11 shows a flowchart showing a method according to an illustrative embodiment.

### DETAILED DESCRIPTION OF THE EMBODIMENTS

In the following description of the preferred embodiment, reference is made to the accompanying drawings which form a part hereof, and in which is shown by way of illustration a specific embodiment in which the embodiment may be practiced. It is to be understood that other embodiments may be utilized and structural changes may be made without departing from the scope of the present application.

In some embodiments, a two phase cooling device may be provided that is thinner and lighter than what is capable with the current state of art.

In some embodiments, a two phase cooling device may be provided that is more accurately charged with a predetermined amount of at least one suitable working fluid, wherein the predetermined amount of working fluid may be controlled with greater accuracy and repeatability.

In some embodiments, a two phase cooling device may be provided that is more accurately charged with a predetermined amount of at least one suitable working fluid, wherein a smaller fraction of contaminants and optionally a small predetermined amount of non-condensable gas, are contained within the cavity after charging.

In some embodiments, a two phase cooling device may be provided with a low profile and minimal lateral extent, where at least one minimally obtrusive port is located in the surface of the device, as opposed to a port protruding from the edge of the device, which is the current state of the art.

In some embodiments, a two phase cooling device may be provided that forms a sub-millimeter thin thermal ground plane.

In some embodiments, a two-phase cooling device is provided that comprises a charging port that contains substantially less dead volume inside the device, compared to the current state of the art.

In some embodiments, a two-phase cooling device may be provided that comprises a titanium metal structure containing a highly accurate and predetermined amount of suitable working fluid, and comprises a high-quality bond that seals the cavity and is less prone to leaking.

In some embodiments, a two-phase cooling device may be provided that comprises a titanium metal structure containing a predetermined amount of at least one working fluid, which is charged with a method that is compatible with titanium manufacturing processes.

In some embodiments, a two-phase cooling device may be provided that comprises a metal structure that is charged with a method that does not require direct mechanical contact between the cooling device charging port and the charging station, during the charging process.

In some embodiments, a two-phase cooling device may be provided that comprises a metal structure containing a predetermined amount of at least one working fluid that is charged with a method that does not require direct mechanical contact between the cooling device charging port and the charging station, during the charging process.

In some embodiments, a two-phase cooling device may be provided that comprises a metal structure that is charged with a method that allows the working fluid to be frozen during the charging process.

In some embodiments, a two-phase cooling device may be provided that comprises a metal structure that is charged with a method that allows the structure and predetermined amount of at least one working fluid to be exposed to low pressure after the working fluid is placed in the cavity, but before the cavity is sealed.

Two phase cooling devices are used in many semiconductor cooling applications, such as heat pipes in desktop and laptop computers. Heat pipes are typically 0.5 mm or significantly thicker and commonly manufactured using copper, aluminum, and respective alloys. In order for a two-phase cooling device to function properly, it must be charged with a suitable working fluid. This is commonly accomplished in heat pipes by: (1) physically connecting the end of a heat pipe to a charging station, (2) applying a vacuum to remove contaminants and non-condensable gas from the heat pipe, (3) flowing working fluid under controlled pressure into the heat pipe, (4) cold welding the end of the heat pipe (i.e. clamping the end shut), and (5) severing the connection between the heat pipe and charging station.

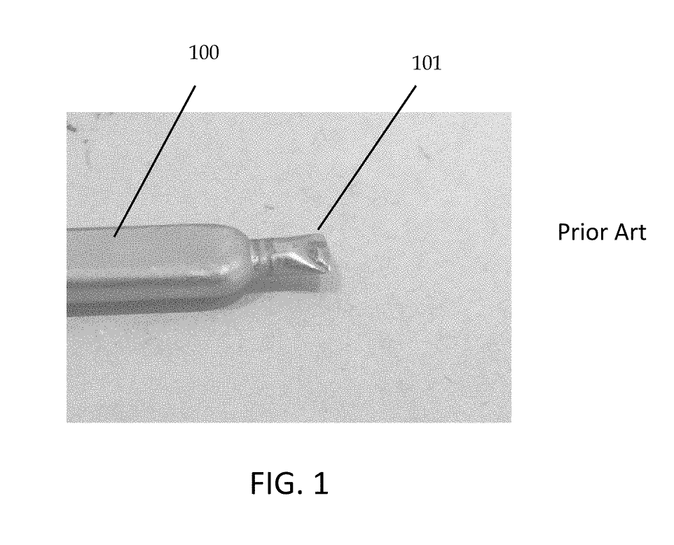

An example from this type of charging is shown in FIG. 1, where the charging port 101 protrudes several millimeters beyond the lateral extent of the heat pipe 100, and is several millimeters thick. The port cannot be removed from this heat pipe without damaging the device. This dead space caused by the protruding port may be undesirable in applications that have confined space requirements. Furthermore, the protruding port creates a region of dead volume inside the cooling device that can inhibit the performance of the cooling device, particularly when the volume of the device becomes small, such as for thin and planar thermal ground planes.

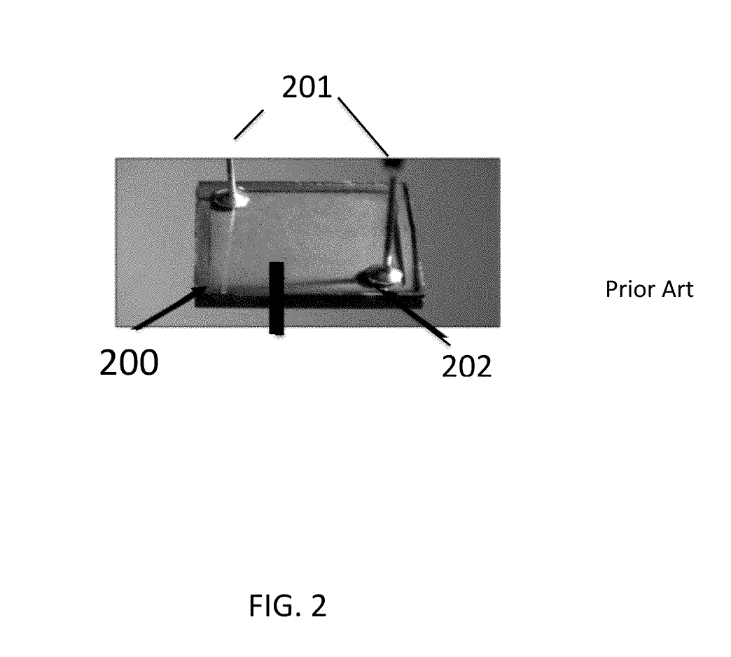

Another example of prior art is shown in FIG. 2, where a planar thermal ground plane 200 is charged using ports 201 that are mounted in the out-of-plane direction of the thermal ground plane (TGP). In FIG. 2, the ports protrude over 1 cm in the out of plane direction, and are clearly not desirable. In this example, the TGP 200 is charged by: (1) physically connecting the ports, 201 (2) applying a vacuum, (3) flowing a working fluid 202 into one port and a vacuum to the second port, (4) sealing the ports, and (5) severing the physical connection between the TGP and the charging station. The length of the ports cannot be substantially reduced without damaging the device.

In embodiments disclosed herein, two-phase cooling devices with low-profile ports are described including low-profile two-phase cooling devices that are less than 1 mm in thickness, and do not have ports that substantially protrude from the cooling device. The charging ports in existing methods have not achieved this goal, as exemplified by the implementations shown in FIG. 1 and FIG. 2.

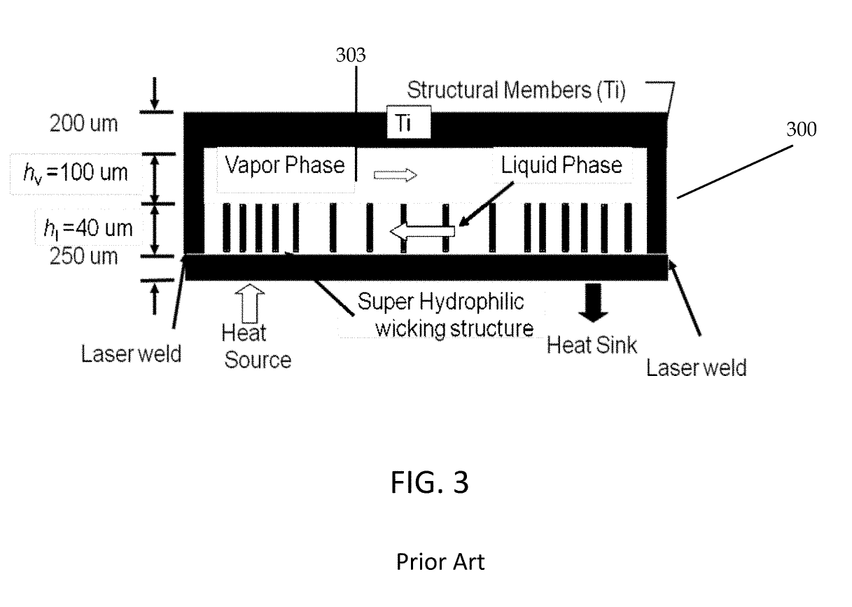

FIG. 3 shows a schematic of the structural components of a thermal ground plane 300 disclosed by U.S. patent application Ser. No. 13/685,579, filed on Nov. 26, 2012, by Payam Bozorgi et al., entitled “TITANIUM-BASED THERMAL GROUND PLANE.” The operation of a two-phase cooling device is disclosed by Bozorgi (2012).

FIG. 3 shows a thermal ground plane 300, where the metal structure is fabricated using titanium or a titanium alloy. A cavity 303 is contained within the metal structure (as shown in FIG. 3).

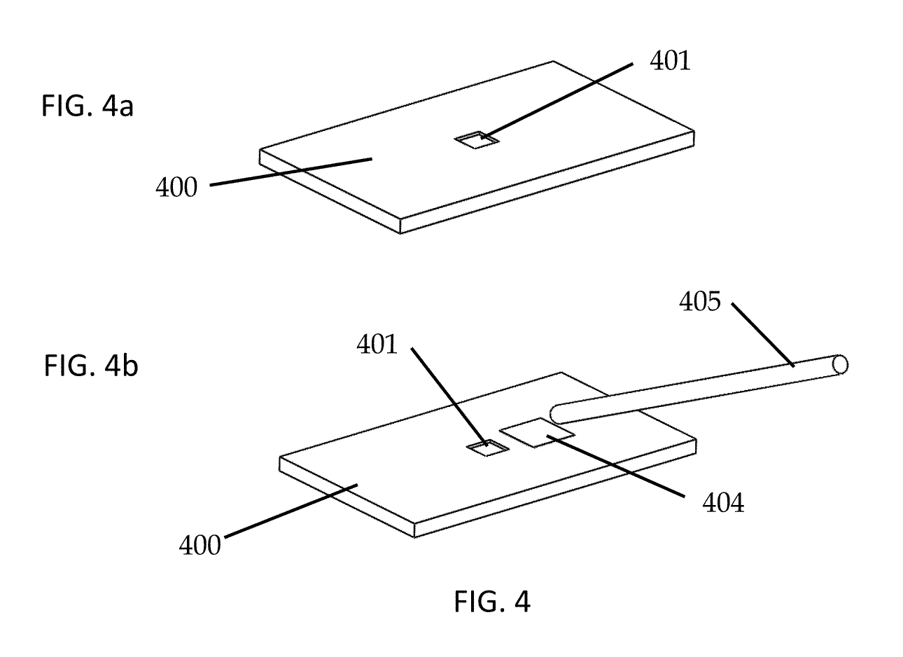

FIG. 4a shows an illustrative embodiment where the metal structure of the cooler or ground plane 400 may be fabricated using titanium (or a titanium alloy). A titanium structure may contain an opening 401 as a charging port in the surface of the titanium. The opening can be optionally placed near the edge of the device. The opening can optionally be made to coincide with a region where two members of the metal structure are mated together. It should be noted that there may be intended use specific advantages for placing the opening at various spatial locations. It should be further noted that there may be intended use advantages as to the size of the opening, which can depend upon the chosen working fluid, operating conditions, etc. The specific examples of size and location of the openings described here are for illustrative purposes, and are not intended to be limiting.

The two-phase thermal ground plane could be ‘charged’ by placing a predetermined amount of a working fluid into the cavity, removing undesirable contaminants, while optionally leaving a small predetermined amount of non-condensable gas, and then sealing the cavity. Opening 401 serves as a port where a predetermined amount of at least one working fluid can be placed into the open cavity. The working fluid can be water, ammonia, ethanol, methanol, liquid helium, mercury, sodium, indium, and other fluids, that are chosen based upon the desired operating conditions of the two-phase cooling device. In one embodiment, high-purity water is chosen as the working fluid. The two-phase cooling device can be exposed to a low-pressure to remove contaminants, while optionally leaving a small pre-determined amount of non-condensable gas. As shown in FIG. 4b opening 401 may be configured to be sealed with a cover 404 when the charging process is complete, shown adjacent the opening but not in a position to be sealed yet in the figure. Cover 404 may be actuated into position with actuator 405.

In an illustrative embodiment, the working fluid may be placed in the cavity under a variety of chosen ambient pressures. For example, in one embodiment the ambient pressure can be chosen to be atmospheric pressure. In other embodiments, the pressure can be much higher or much lower than atmospheric pressure, depending upon the chosen working fluid.

In some embodiments, the two-phase cooling device port may be optionally not required to be in physical communication with a charging station, when the working fluid is being injected into the cavity. This provides flexibility in the methods that can be used for injecting a predetermined amount of working fluid into the cavity. For example, one can use pipette-type devices, inkjets, precision syringes and needles, microfluidic devices, and other fluid injection devices. This allows one to accurately and reliably inject anywhere from 10⁻⁴ grams to 10² grams of working fluid with higher tolerance and higher repeatability than can be accomplished with current cooler charging methods.

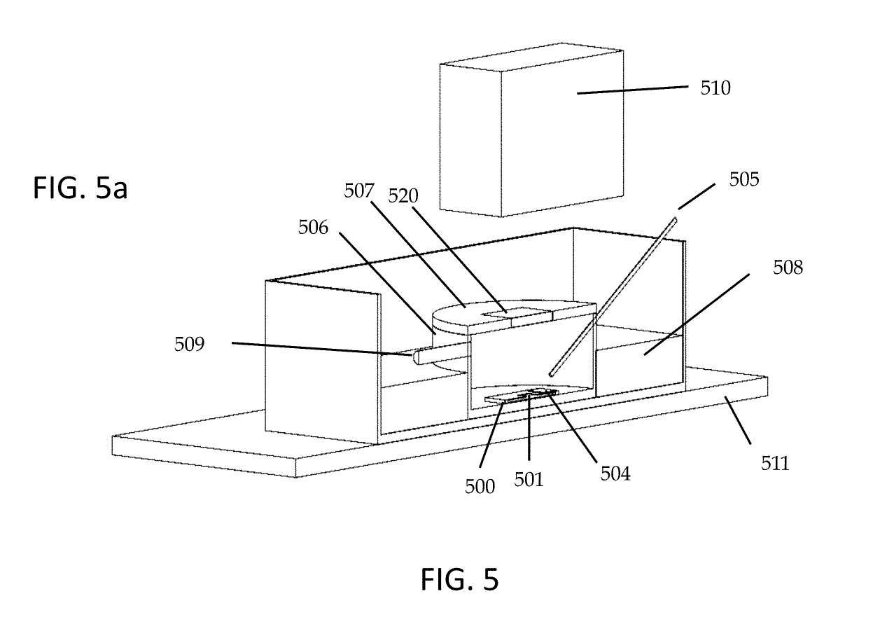

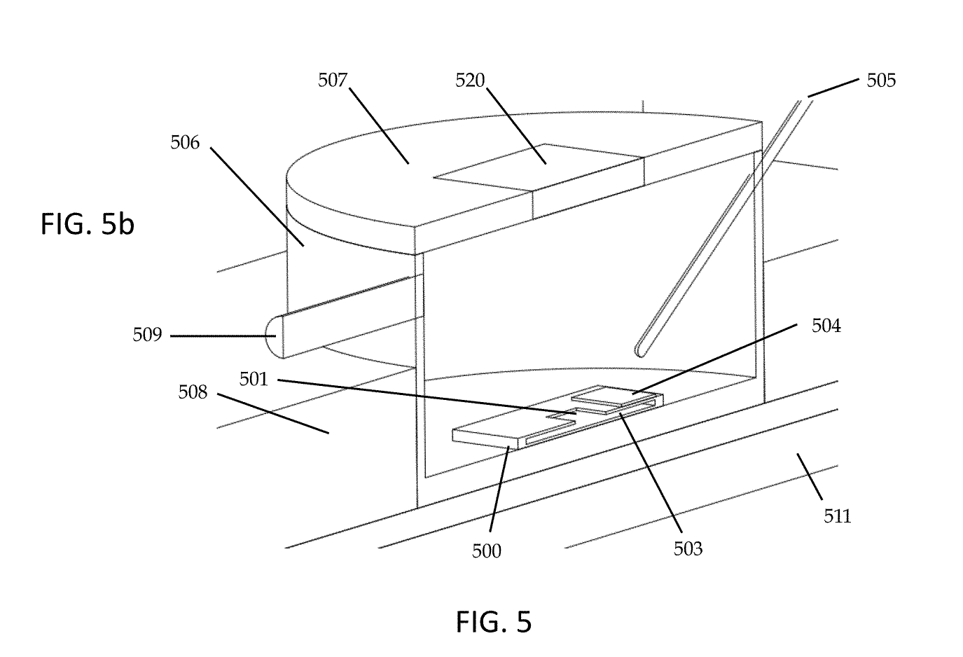

FIG. 5a and FIG. 5b show one embodiment of a glass vacuum chamber 506 charging apparatus that can optionally be used to charge the Ti-based thermal ground plane (TGP) 500. Elements of the glass vacuum chamber apparatus may include: an access port 507 to allow placement of TGP 500 within the chamber and access for placing working fluid in the TGP cavity, a cooling bath 508 (comprised of liquid nitrogen or other cold liquid) to freeze the working fluid, a vacuum port 509 to connect to a vacuum pump for evacuating the chamber, an actuator 505 to manipulate the position of the cover 504 relative to the opening 501. Access port 507 can be sealed with a removable lid that is configured with optically transparent window 520 to transmit light from the laser welder to the structure. Optically transparent window 520 could be manufactured from quartz or other transparent material. FIG. 5b shows details of the thermal ground plane 500 with opening 501, cover 504, and cavity 503. The illustrative vacuum chamber charging apparatus shown in FIG. 5a and FIG. 5b have demonstrated beneficial results and the concepts are scalable to production implementations.

In one embodiment, the vacuum chamber access port 507 is opened, the thermal ground plane 500 metal structure containing the cavity 503, e.g. an uncharged TGP, is placed in the vacuum chamber 506, and the cover 504 is positioned next to the opening in the surface, as shown in FIG. 5a and FIG. 5b. The cavity contained by the metal structure is injected with a predetermined amount of working fluid. The access port 507 is then sealed by replacing the removable lid, and connected to the vacuum chamber through vacuum port 509 (as shown in FIG. 5a and FIG. 5b). The metal structure is exposed to a low temperature from cooling bath 508 to freeze the working fluid into a solid phase. In one embodiment, a liquid nitrogen bath is placed around the lower portion of the vacuum chamber charging apparatus to freeze liquid water liquid into solid water (i.e. ice), in other embodiments dry ice and methanol or ethanol is used, in other embodiments a wide variety of cold liquids or gasses can be optionally used. Optionally, by cryogenic or deep freezing the working fluid, the rate of sublimation can be reduced, compared to mildly freezing the working fluid. Thus temperatures from 0 deg. C. to full cryogenic ranges as far a −270 deg C. may be employed. This is advantageous, when the amount of working fluid injected into the cavity must be controlled with high accuracy, for example to within the micro-gram or milli-gram accuracy, or when very low-pressure is exposed to the structure that could promote evaporation or sublimation. Optionally, when the rate of evaporation or sublimation is well-characterized, one may choose a different low temperature that is more compatible to a chosen large-scale manufacturing process.

In other embodiments, the metal structure can be exposed to a low temperature by a variety of methods, including but not limited to, large heat sinks, thermal-electric coolers, refrigeration, gas expansion, and any other type of cooling process.

Once the working fluid is at a sufficiently low temperature (e.g. cryogenically frozen, as is the case for some embodiments), the metal structure can be exposed to low pressure by connecting the vacuum chamber to a vacuum pump. The low pressure can range greatly, between several atmospheres of pressure to pico-Torr levels of pressure, for example, depending upon the chosen working fluid and other manufacturing preferences. In a preferred embodiment, where the chosen working fluid is water, and the water has been cryogenically frozen, the low-pressure level can be chosen to be at the micro-Torr or milli-Torr range. The advantage of optionally deep freezing the working fluid and optionally choosing the low-pressure to be in the micro-Torr to milli-Torr range is that this process can remove significant amounts of contaminants, while optionally leaving a small pre-determined amount of non-condensable gas, in the cavity, while losing negligible amounts of working fluid through the process of sublimation, which provides a very accurate amount of working fluid contained within the cavity of the two-phase cooling device. In addition, the process of applying a low temperature before applying a low pressure to the structure can significantly reduce unwanted condensation of the working fluid onto the outside of the metal structure. This can be important for obtaining a high-quality bond between the cover and the metal structure, which is discussed below. Exact charging process temperatures and pressures will vary with the cooler design, the working fluid and the chosen large-scale manufacturing process.

The structure is exposed to low temperature and low pressure for a specified period of time, which can range from several seconds to a tens of minutes, depending upon many factors, including: the chosen working fluid, the predetermined amount of working fluid required, the size of the opening in the metal surface, the level of low temperature, the level of low pressure, and many other design factors. In some embodiments, the specified period of time can range from several seconds to several minutes.

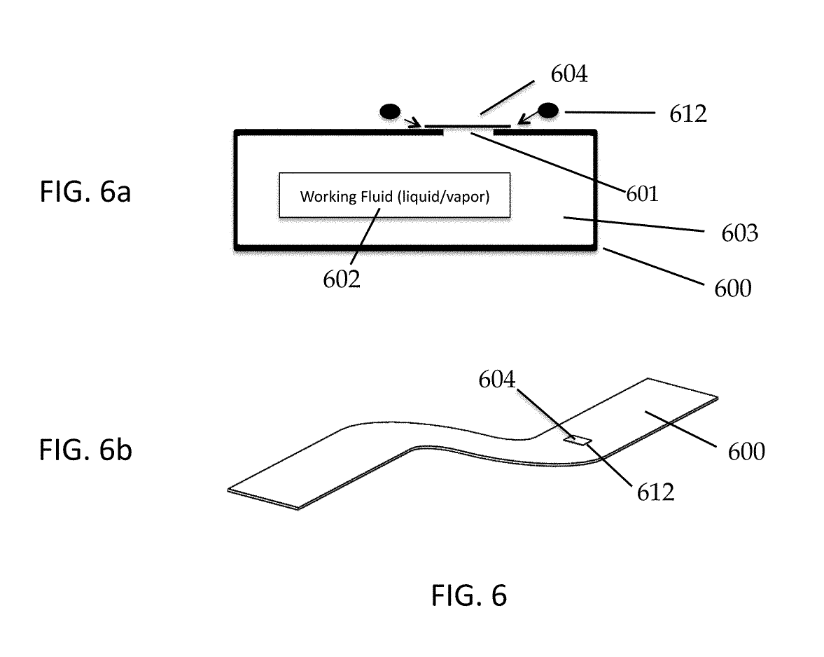

After the specified period of time, and while the structure is still being exposed to low temperature and low pressure, the cover may be positioned directly above the opening in the surface. In an example embodiment, the cover is positioned from being in close proximity to the opening (as shown in FIG. 4b), to being directly over the opening (as shown in FIG. 6a and FIG. 6b). In an example embodiment, this can be accomplished by using the actuator 505 shown in FIG. 5a and FIG. 5b. In other embodiments, which are compatible with large-scale manufacturing processes, the cover can be positioned by a variety of automated pick and place equipment.

Once the cover 504 is positioned to encompass the opening 501 in the surface (as shown in FIG. 5a and FIG. 5b), the cover is bonded to the metal structure to provide a hermetic seal for the cavity. In a one embodiment, where the cooler metal structure is chosen to be titanium or a titanium alloy, a laser welder 510 can be used to micro-weld the cover to the titanium metal structure (as shown in FIG. 5a). The thermal ground plane can be positioned to the laser welder with positioning stage 511. Laser welding has the advantage in that is a form of non-contact welding, such that the cover and structure can be welded together, while simultaneously being exposed to the low temperature and the low pressure environment in the chamber. Furthermore, under low temperature and low pressure, there exist very few contaminant molecules in close proximity of the region being welded, and as a result, the weld between the cover and structure can be of very high quality, and will produce a highly reliable and robust hermetic seal. In one embodiment, the cover and structure are welded by a pulsed Nd:YAG laser, which heats the titanium metal locally, but does not heat the metal structure at non-local distances from the point of the weld. Another advantage of laser welding titanium is that there are limited contaminants that could contaminate the charged cavity, and negatively affect the performance of the two-phase cooling device. Furthermore, the laser welder or metal structure can be translated using micro-positioning stages to facilitate the welding process.

A low-profile port two-phase cooling device according to this disclosure was built and tested. The cooling device was made by wet etching titanium, and was of a size suitable for a personal computer application (for example, a mobile electronic device), 10 cm long, 3 cm wide, and 800 microns thick. The cooling device was charged with 800 milli-grams of lab grade pure water, and then placed in a liquid nitrogen bath (77 Kelvin) for approximately 20 minutes. Then a vacuum of approximately one micro-Torr was applied for approximately 20 minutes, followed by welding a cover over the opening, producing a working very low profile two-phase cooling device.

In some embodiments, the cover and structure can be bonded by other welding techniques, including but not limited to: diffusion bonding, friction stir, oxy-fuel, resistance welding, ultrasonic, magnetic pulse, exothermic, high frequency, hot pressure, induction welding, roll welding, brazing, soldering, shielded metal arc, flux-cored arc, gas tungsten arc, gas metal arc, submerged arc, electroslag, and using energy sources, including but not limited to, gas flame, electric arc, electron beam, friction, ultrasound, and many others, without loss of generality.

In some embodiments, the metal structure can optionally comprise a variety of metals, for example, scandium, titanium, vanadium, chromium, manganese, iron, cobalt, nickel, copper, zinc, yttrium, zirconium, niobium, molybdenum, technetium, ruthenium, rhodium, palladium, silver, cadmium, hafnium, tantalum, tungsten, rhenium, osmium, iridium, platinum, gold, mercury, rutherfordium, dubnium, seaborgium, bohrium, hassium, copernicium, aluminum, gallium, indium, tin, thallium, lead, bismuth, polonium, germanium, and their associated alloys.

In some embodiments, the structure can optionally comprise: ceramics, glass, polymers, liquid crystal polymers, and other structural materials.

FIG. 6a and FIG. 6b show examples of two-phase cooling devices with low-profile ports. FIG. 6a is a schematic of one such embodiment. In this embodiment, a two-phase cooling device 600 is comprised of a cavity 603 formed from a metal structure or a metal alloy structure with an opening 601 in the surface of the structure. A predetermined amount of suitable working fluid 602 is contained within the cavity. A cover 604 for opening 601 is bonded with a bonding material 612 to the metal structure, The bonding material may be a separate welding agent or may be formed by melting a portion of the cover 604 and cooling device 600 material together.

FIG. 6b shows an embodiment, wherein the cooler 600 metal structure and cover 604 is titanium and/or a titanium alloy. The working fluid is a predetermined amount of 10⁻⁶ to 10³ grams (with accuracy ranging between micro-grams to milli-grams) of pure water. The titanium cover bond is comprised of a pulsed-laser micro-weld, so that cover 604 is bonded directly to cooling device 600 so that the inner cavity is hermetically sealed. In this embodiment, bonding material 612 is formed by melting a portion of cover 604 and cooling device 600.

Optionally in several embodiments, the cover can be thin and/or the structure surface recessed so that the cover is nearly flush (typically to within 0-250 microns) with the structure surface.

FIG. 6b shows an example embodiment, which illustrates the low-profile configuration of two-phase cooling devices 600 according to some embodiments. These types of low-profile devices have applications where heat must be transferred efficiently, and only limited space is available. FIG. 6b further shows that the shape of the two-phase cooling device can be made to conform to a variety of plan-form (i.e. lateral footprint) shapes. In addition, because the devices can be made thin (sub-millimeter), they can be made to conform in the out-of-plane direction. This allows for true three-dimensional routing of heat flow, while maintaining a thin and low-profile configuration.

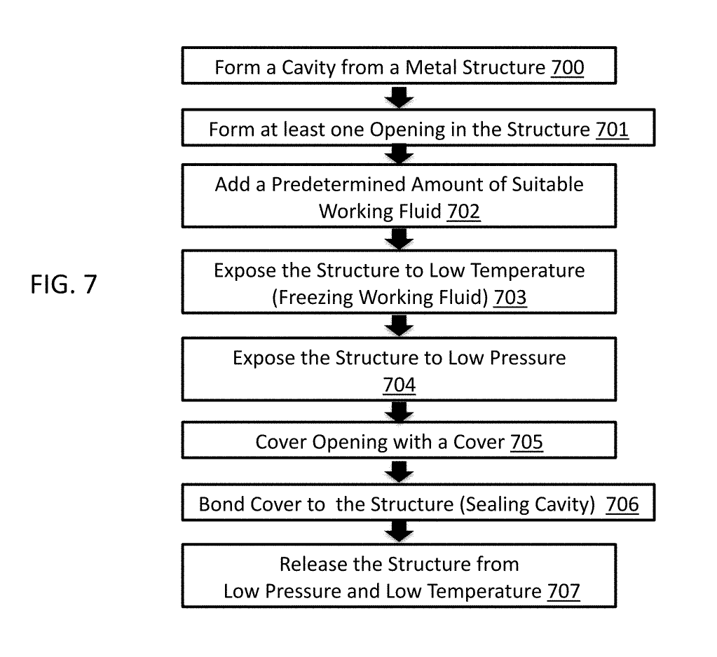

FIG. 7 shows a flowchart depicting a method used to form one embodiment of the current invention. First a cavity is formed from a metal structure or a metal alloy structure 700. Then at least one opening is formed in the metal structure 701, which could optionally be located in at least one surface of the structure, optionally located in predominantly one side or more sides of the structure. This opening acts as a port that provides access to the cavity, so that a predetermined amount of at least one suitable working fluid can be placed inside the cavity 702. The metal structure containing the working fluid is then exposed to a sufficiently low temperature, thereby freezing the working fluid 703. After the working fluid is frozen, the structure is exposed to low ambient pressure, thereby extracting contaminants, while optionally leaving a small predetermined amount of non-condensable gas in the cavity 704. After a period of time, the opening is covered with a metal cover 705. The metal cover is bonded to the metal structure to hermetically seal the cavity 706. The hermetic seal prevents the working fluid from leaving the cavity, and prevents contaminants and non-condensable gas from entering the cavity. Finally, the structure is released from exposure to the low pressure and low temperature environment 707.

Optionally in yet another embodiment, the cover can be thinned and/or the structure surface can be recessed so that the cover becomes nearly flush (typically to within 0-250 microns) with the structure surface.

In a one method embodiment, the metal structure and cover are fabricated from titanium and/or a titanium alloy. The working fluid is chosen to be a predetermined amount of 10⁻⁶ to 10³ grams (with accuracy ranging between micro-grams to milli-grams to grams) of pure water. The low temperature is chosen to be between 0° C. and cryogenic levels. The low pressure is chosen to be in the micro-Torr to milli-Torr range. The titanium cover is pulsed-laser micro-welded to the titanium structure, so that the cavity is hermetically sealed.

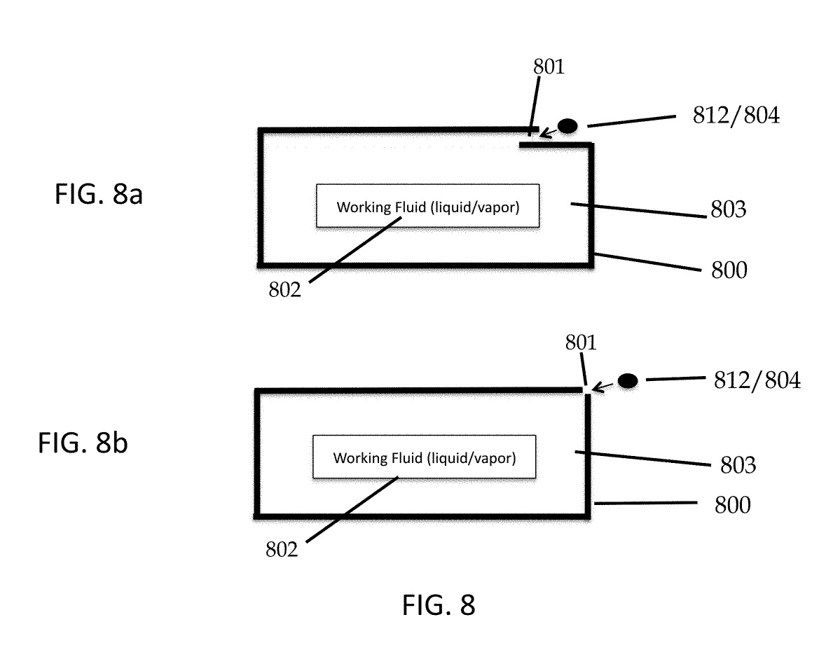

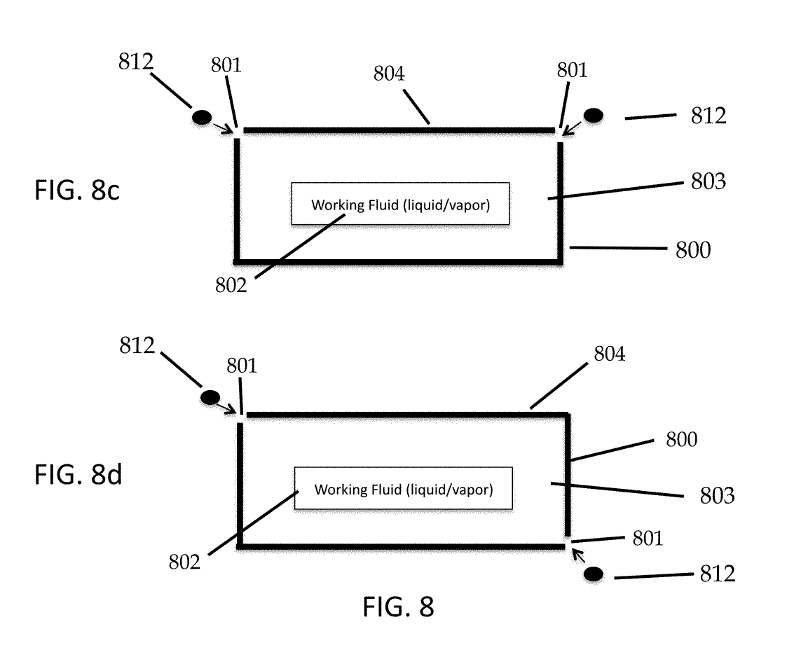

FIGS. 8a, 8b, 8 c, and 8d show device embodiments. These embodiments are illustrative and not intended to be limiting. In FIGS. 8a and 8b, the opening 801 in the surface of the cooler structure may be sufficiently small or appropriately configured, such that a distinct and separate cover 804 is not required, and the metal structure is bonded directly to itself, so that the cavity 803 is sealed, whereby the bonding material 812 forms the cover 804. This bond could be optionally formed by a pulsed-laser micro weld. The bonding material 812 could be formed by melting a portion of the metal structure of device 800. In FIG. 8b, at least one opening 801 is in close proximity to at least one edge of the cooling device 800 metal structure, and may be sufficiently small or appropriately configured, such that a distinct and separate cover 804 is not required, and the metal structure is bonded directly to itself, so that the cavity is sealed by a pulsed-laser micro weld and the bonding material 812 is formed by melting a portion of the metal structure with another portion of the metal structure.

FIGS. 8c and 8d show embodiments where the “cover” 804 is comparable in size to the cooling device 800 structure. In FIG. 8c, opening 801 is predominantly one side of the metal structure, wherein cover 804 forms substantially one side of the metal structure, and covers opening 801 and is bonded to seal cavity 803. The cavity contains a predetermined amount of working fluid 802. The cover comprises predominantly one side, an end or other face of the metal structure, and is bonded to the metal structure. Bonding material 812 is used to seal the cavity to prevent the working fluid from leaving the cavity, and prevent contaminants and non-condensable gas from entering the cavity. The bonding material 812 could be formed by melting a portion of the metal structure with another portion of the metal structure.

FIG. 8d shows the opening 801 being two sides of the cooling device 800 metal structure, whereby “cover” 804 is half of the structure. The device comprises a metal structure, an opening in the metal structure that comprises predominantly two sides of the metal structure. The cavity 803 contains a predetermined amount of at least one working fluid 802. The cover 804 comprises predominantly two sides of the metal structure and is bonded to the metal structure, sealing the cavity to prevent the working fluid from leaving the cavity, and contaminants and non-condensable gasses from entering the cavity.

The embodiments shown in FIG. 8c and FIG. 8d are similar to the embodiment shown in FIG. 6a, with the modification that the opening and the cover are extended to encompass one or more sides of the metal structure, in addition to the surface of the metal structure.

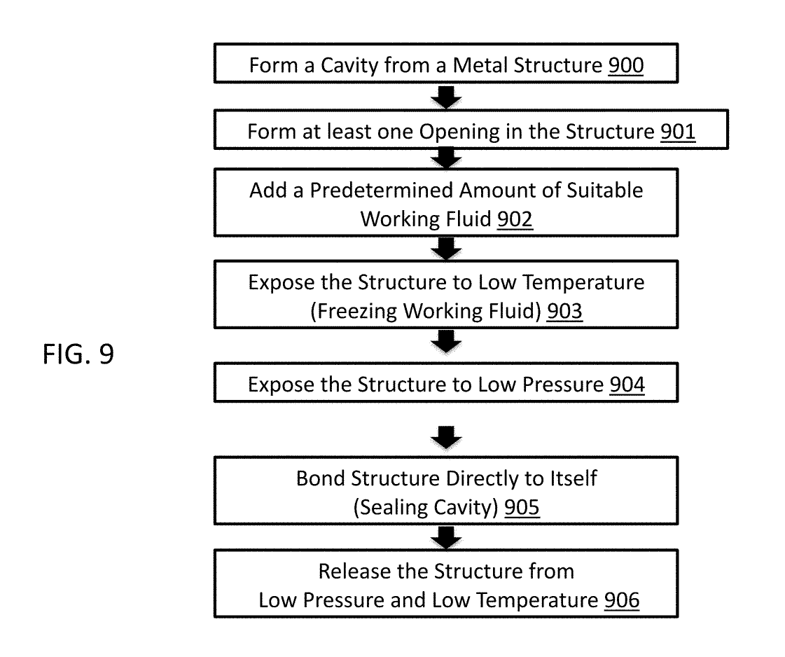

FIG. 9 shows a flowchart depicting a method used to form additional embodiments. First a cavity formed from a metal structure or a metal alloy structure 900. Then at least one opening is formed in the metal structure, which could be located in at least one surface, comprised of at least one side of the structure, or in close proximity to at least one edge 901. This opening acts as a port that provides access to the cavity, so that a predetermined amount of suitable working fluid can be placed inside the cavity 902. The metal structure containing the working fluid is then exposed to a sufficiently low temperature, thereby freezing the working fluid 903. After the working fluid is frozen, the structure is exposed to low ambient pressure 904, thereby extracting contaminants, while optionally leaving a predetermined amount of non-condensable gas in the cavity. After a period of time, the metal structure is bonded directly to itself to hermetically seal the cavity 905. The hermetic seal prevents the working fluid from leaving the cavity, and prevents contaminants and non-condensable gas from entering the cavity. Finally, the structure is released from exposure to the low pressure and low temperature environment 906.

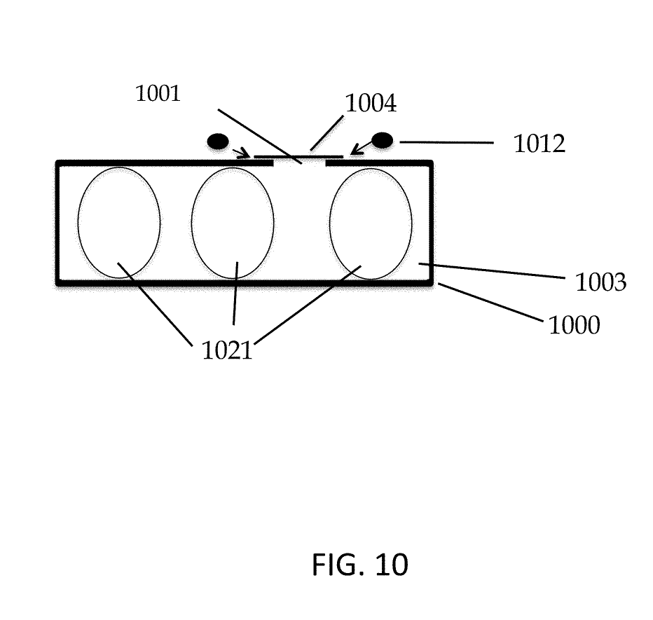

FIG. 10 shows an illustrative embodiment of an insulator device. Device 1000 comprises a metal structure with opening 1001. Cover 1004 is sealed to device 1000 with bonding material 1012. Cavity 1003 is at a low pressure 10⁰ to 10⁻⁶ Torr. Mechanical supporting structure 1021 resides in cavity 1003 to support the metal structure. In certain embodiments, mechanical supporting structure 1021 is comprised of a low thermal conductivity material, such as a plastic honeycomb structure or other structural material. In certain embodiments, the metal structure is formed from titanium or a titanium alloy. In certain embodiments, the bond is a micro-laser weld.

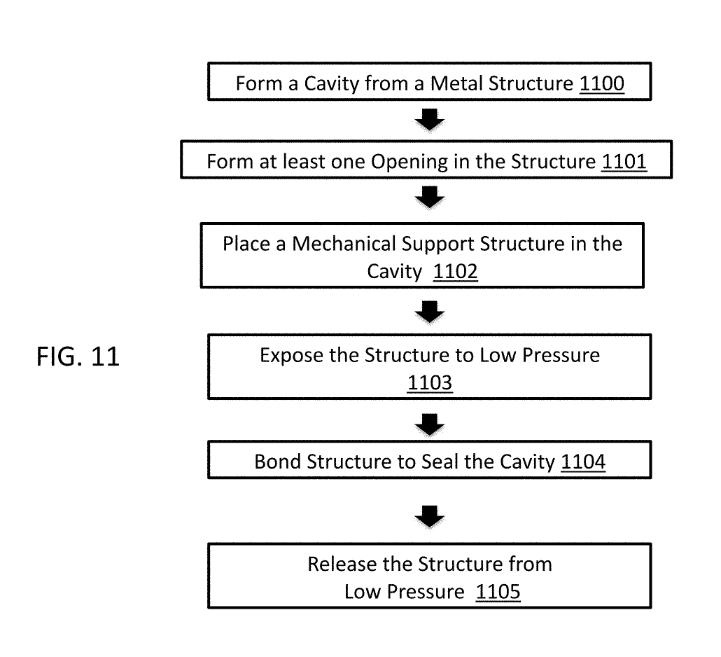

An insulator device could be formed according to the method shown in FIG. 11, by forming a cavity from a metal structure 1100, forming at least one opening in the structure 1101, placing a mechanical support structure in the cavity 1102, exposing the structure to low pressure (1103) of 10⁰ to 10⁻⁶ Torr, bonding structure to seal the cavity 1104, releasing the structure from low pressure 1105. In certain embodiments, the metal structure is formed from titanium or a titanium alloy. In certain embodiments, the bond is formed by micro-laser welding the titanium structure.

The embodiments described herein are exemplary. Modifications, rearrangements, substitute elements and processes, etc. may be made to these embodiments and still be encompassed within the teachings set forth herein.

1-2. (canceled)

3. A method for charging a two-phase cooling device, comprising;
forming a cavity from a metal structure;
forming at least one opening in the structure;
adding a predetermined amount of working fluid to the cavity;
exposing the structure containing said working fluid to a sufficiently low temperature, thereby freezing said working fluid;
exposing the structure, containing the frozen working fluid, to a low pressure, thereby extracting non-condensable gas and contaminants from the cavity;
sealing said opening with a seal;
releasing the structure from exposure to the low pressure and the low temperature.

4-12. (canceled)

12. The method of claim 3, further comprising:
leaving a predetermined amount of noncondensable gas in the cavity;
sealing said opening with a cover, wherein the cover is nearly flush with the structure; and
releasing the metal structure from exposure to the low pressure and the low temperature.

13-14. (canceled)

15. The method of claim 3, wherein the opening is one of at or near an edge of the metal structure and the seal comprises a welded seal joining the open portions of the edge to form the seal.

16. The method of claim 3, wherein the low temperature is between 0° C. and −270° C., wherein the low pressure is less than 10⁰ Torr.

17. The method of claim 3, wherein sealing the opening comprises at least one of welding and bonding a cover to the opening, wherein welding the cover comprises pulsed-laser micro-welding the cover to the metal structure.

18-20. (canceled)

21. The method of claim 3, further comprising leaving a predetermined amount of noncondensable gas in the cavity

22. The method of claim 12, wherein the cover for the titanium structure opening is comprised of at least one of a bonded cover or a pulsed-laser micro-weld.

23. The method of claim 3, wherein the structure and cover are made from titanium or a titanium alloy.

24. The method of claim 3, wherein the working fluid is a predetermined amount of pure water, or any other working fluid.

25. The method of claim 3, wherein the amount of the predetermined amount of working fluid ranges between 10⁻⁴ grams and 10⁻³ grams.

26. The method of claim 3 further comprising leaving a predetermined amount of noncondensable gas in the cavity.
